(19) United States
(12) Patent Application Publication
(10) Pub. No.: US 2008/0048344 A1
(43) Pub. Date: Feb. 28, 2008

(54) HIGH PERFORMANCE IC PACKAGE AND METHOD

(76) Inventors: Robert Lyn, Thornhill (CA); John Persic, Toronto (CA); Morgan Lee Upshall, Oshawa (CA)

Correspondence Address: HAYES SOLOWAY P.C., 3450 E. SUNRISE DRIVE, SUITE 140, TUCSON, AZ, 85718, US

(21) Appl. No.: 11/776,517

(22) Filed: Jul. 11, 2007

Related U.S. Application Data
(62) Division of application No. 11/055,644, filed on Feb. 10, 2005, now abandoned.

(51) Int. Cl. H01L 23/52; H01L 23/48; H01L 29/40

(52) U.S. Cl. 257/784

(57) ABSTRACT

A novel wire-based interconnect IC package is described as well as the method of designing and the method of producing the IC package. The IC package includes one or more signal carrying wires as well as ground return wires associated with each signal carrying wire to electrically couple a chip to a carrier substrate. Both the signal carrying wire and its associated ground return wires may be insulated, however at least the signal carrying wire or the ground wires are insulated. The inductance of the signal carrying wires can be kept low by keeping the wirebonds as short as possible and by positioning a number of ground wires symmetrically about and in close proximity to the signal carrying wire. The signal carrying wires and the ground return wires are connected to bond pads on the chip and to bond fingers on the carrier substrate to couple the chip to the substrate. Further, the bond pads may be staggered such that the effective pitch of the bond pads is less than the diameter of the wire, and the bond fingers may be positioned on a bond finger ring and to bonding locations outside the ring providing an effective pitch of the bond fingers of less than the diameter of the wire.

### FIELD OF INVENTION

The present invention relates generally to first level interconnect IC packages, and more particularly to novel wire-based interconnect packages.

### BACKGROUND OF THE INVENTION

First-level IC packaging performs the function of electrically connecting a silicon chip to a larger carrier and enabling it to be safely handled and assembled into an electrical system. Key objectives of IC packaging are to route the connections of the chip to a carrier substrate in a cost-effective way, to minimize the form factor of the final IC package, and to minimize degradation of electrical performance that can be caused by packaging parasitics such as inductance, resistance and capacitance. Therefore, an electrical objective is to maintain signal integrity despite the presence of packaging parasitics; in other words, to provide an electrical path in the package on which electrical data can travel without undue noise, distortion or interference from parasitic elements along that path.

The negative effects of these parasitics can increase with operating frequency. As chip and system speeds now routinely operate in the Gigahertz range, it is more necessary than ever to carefully select packaging technologies, which do not interfere with the proper functioning of the system.

Currently, the following two major packaging technologies are used within the IC packaging industry for chip-to-carrier, or “first-level”, interconnections: (1) Wire-based interconnection (90-95% of chips connected) and (2) bump-based interconnection (5-10% of chips connected).

In the case of the wire-based interconnection, a wire is bonded from a ‘bond pad’ on the silicon chip to a ‘bond finger’ on a carrier substrate. The resulting interconnection is referred to as a “wirebond” and the package is referred as a “wire-based IC package”. Electrical parasitics from this method of interconnection arise primary from the loop inductance of wire, the self inductance of the wire, capacitive coupling.

With this method, functional limitations may arise with increased frequencies. The practical limit for this method, as determined by the frequency at which there is −15 dB return loss, has been estimated at less than 1 GHz for 5 mm long wirebonds.

With bump-based interconnects, solder bumps are used instead of bonding wires. These bumps are located on the chip and each bump is soldered to a corresponding pad on a carrier substrate. During package assembly, this array of bumps on the chip must be carefully aligned with an associated array of pads on the carrier substrate. The interconnection scheme from chip bump to carrier pad needs to be determined at the time that the carrier substrate is designed; it can be difficult and expensive to reassign a bump on the chip to a different pad on the carrier substrate from the one placed directly below it. High density bump-based packages typically drive a much higher chip carrier, or substrate cost to ‘route’ the bumps.

In contrast, the wire-based interconnect method allows for the connection scheme between the bond pads and bond fingers to be determined at the later IC packaging manufacturing phase. This allows for electrical design flexibility at a later stage of IC packaging, which is generally desirable.

With bump-based interconnects, each bump is relatively large in diameter (3-5 mil) in comparison to the bond wire (1 mil). A bump interconnect is also much shorter than a wire interconnect. As a result, the inductance of a conventional bump is typically much lower than that of a conventional wire and can be lower by an order of magnitude of approximately 10×. Consequently, higher speed performance is possible with bump-based as compared to conventional wire-based IC packages.

Nevertheless, due to a much lower implementation cost and to the design flexibility offered by the wire-based interconnect method as compared to bumped-based interconnect method, it is desirable to develop methods to extend the operating range of wirebonds to higher frequencies than conventional wire-based interconnect technology will allow.

As previously discussed, interconnects with lower inductance are associated with less signal distortion. Transmission line theory explains how inductance can be reduced by the proximity of a parallel adjacent wire carrying a DC-voltage return current “ground wire”. Therefore, by placing a signal-carrying wirebond as close as possible to its return path will reduce its inductance.

Theory also explains the relationship between reduced inductance and reduced impedance, and why it is desirous to keep a constant impedance along the signal path in an IC package. By reducing the inductance associated with a traditional signal-carrying wirebond connection, the impedance of the wirebond connection is more closely matched to that of the rest of the IC package.

Additionally, it is desirous for the return path to be of the lowest impedance possible in order to promote the most uniform, non-transient, current. This will reduce radiation from the ground wire to the signal-carrying wire. Theoretically, to maximize these design benefits, a signal-carrying line would be closely surrounded by an infinite number of ground return wires placed in close proximity to the signal-carrying line. Practically, this would look like a shielded cable.

Using conventional uninsulated wire in present wire-based interconnect IC packages, the closest distance that can be achieved between two wirebonds is on the order of a one bond wire diameter. Presently, wire on the order of 25 micrometers is typically used for standard IC packages using gold bonding wire; however, there is a trend to finer wire diameters, with leading edge bond wire being 12.5 micrometers. Nevertheless, there continues to be a significant number of IC chip applications that use 30 micrometer diameter wire, particularly for a few niche product applications. Due to the tolerance of the wirebonding method, subsequent encapsulation and molding operations, and other operations such as hermetic sealing, attempting a distance of less than this could cause adjacent wires to short, disrupting system operation.

If multiple ground returns were placed in close proximity to the signal carrying wire, this would reduce the impedance of the return path. With conventional, uninsulated wires, the number and proximity of the ground wires to the signal wire is limited by the required gap between the wires to prevent shorting of the ground wires to the signal wire. On the chip, the distance between bond pads is typically on the order of 35-50 micrometers for leading edge chips, 60-80 micrometers for advanced chips, and greater than 80 micrometers for standard chips; on the carrier substrate, the distance between bond fingers is around 100 micrometers.

Previous attempts have been made to improve the signal integrity of a high speed line by reducing cross-coupling due to mutual inductance between the high speed line and its adjacent wires.

U.S. Pat. No. 6,538,336, which issued to Secker, et al on Mar. 25, 2003, describes a device and method in which cross-coupling between adjacent signal lines is reduced by placing DC or slow-switching lines in between signal lines of interest. In U.S. Pat. No. 5,606,196, which issued to Lee, et al on Feb. 25, 1997, reduction in crosstalk between two wirebonds is achieved in a device by placing a “current looper” bond wire in between the two. This screening wire serves no functional electrical connection purpose between the chip and substrate.

Neither of these attempts creates a high-speed signal wire by reducing the self-inductance of the high-speed wirebond by placing it adjacent to one or more wirebonds carrying DC current.

Therefore there is a need for a wire-based interconnect IC package capable of maintaining signal integrity at higher operating frequencies than can be achieved with conventional wire-based IC packages.

### SUMMARY OF THE INVENTION

The present invention is directed to a wire-based interconnect IC package comprising one or more signal carrying wires adapted to electrically couple a chip to a carrier substrate, and one or more ground current return wires positioned adjacent to each signal carrying wire and adapted to electrically couple the carrier substrate to the chip, wherein each of the signal carrying wires and/or the adjacent ground return wires are insulated. The invention is further directed to a method of designing the wire-based interconnect IC package and to a method of producing the wire-based interconnect IC package.

In accordance with one aspect of the invention, the signal carrying wires are insulated wires, the ground return wires are insulated wires or both the signal carrying wires and the adjacent ground return wires are insulated wires.

In accordance with a further aspect of the invention, the ground return wires are substantially parallel to the adjacent signal carrying wire over a substantial length of the signal carrying wire, and/or the ground return wires are positioned substantially symmetrically about the adjacent signal carrying wire.

In accordance with a specific aspect of the invention, the signal carrying wire and the ground return wires each have a conductive core with a diameter less than 25 micrometers, and the conductive core of the ground return wires are positioned a distance of less than the wire diameter from the conductive core of the signal carrying wire over a substantial length of the signal carrying wire.

In accordance with a further aspect of the invention, the ground return wires are positioned substantially adjoining the signal carrying wire over a substantial length of the signal carrying wire.

In accordance with another aspect of the invention, the wires are connected to bond pads on the chip and are connected to bond fingers on the carrier substrate to couple the chip to the substrate. Further, the bond pads may be staggered such that the effective pitch of the bond pads is less than one wire diameter, and the bond fingers may be positioned on a bond finger ring and to bonding locations outside the ring providing an effective pitch of the bond fingers of less than one wire diameter.

The method of producing a wire-based interconnect IC package for electrically coupling a chip to a carrier substrate comprises selecting one or more locations on the chip and one or more corresponding locations on the carrier substrate for coupling by signal carrying wires, selecting further locations on the chip and corresponding locations on the carrier substrate adjacent to each signal carrying wire location for coupling by ground return wires, selecting predetermined lengths of wire as signal carrier wires and as ground return wires, wherein the signal carrying wires and/or ground return wires are insulated wire, and bonding the signal carrying wires and the ground return wires to the chip and the carrier substrate at the selected locations.

In accordance with an aspect of the invention, each signal carrying wire location on the chip and its corresponding location on the carrier substrate are selected to minimize the distance between the locations, and the length of each signal carrying wire is selected to minimize the wire length between the locations.

In accordance with another aspect of the invention, three or more adjacent ground wire locations are selected for each signal carrier wire location selected. The ground wires are bonded to the chip and to the carrier substrate, and may be positioned such that the ground return wires are substantially parallel to their adjacent signal carrying wire over a substantial length of the signal carrying wire and/or may be positioned such that the ground return wires are substantially symmetrically about their adjacent signal carrying wire.

In accordance with another aspect of the invention, the bonding locations on the chip may be staggered to provide an effective pitch between the bonding locations of less than one wire diameter, and the bonding locations on the carrier substrate may also be staggered to provide an effective pitch between the bonding locations of less than one wire diameter.

In accordance with a specific aspect of this invention, bond pads may be positioned at the bonding locations on the chip and bond fingers may be positioned at the bonding locations on the carrier substrate.

The method of designing a wire-based interconnect IC package having one or more signal carrying wires and a number of ground current return wires associated with each signal carrying wire for electrically coupling a chip to a carrier substrate wherein each signal carrying wire inductance is minimized to closely impedance match the signal carrying wire to the IC package comprises determining the signal wire and/or the ground return wires to be insulated, each signal carrying wire length, the number of ground return wires associated with each signal carrying wire, the ground return wire lengths, the distance between the ground return wires and their associated signal carrying wire, and the position of the ground return wires relative to their associated signal carrying wire.

In accordance with an aspect of this invention, the length of each signal carrying wire is determined by the distance between a bonding location on the chip and a bonding location on the substrate to be coupled by the signal carrying wire. The bonding location on the chip and the bonding location on the substrate are selected to minimize the length of the signal carrying wire.

In accordance with another aspect of the invention, the number of ground return wires associated with each signal carrying wire is determined by the number of available bonding locations on the chip and/or the number of bonding locations on the substrate. This may permit three or more ground return wires to be associated with each signal carrying wire.

In accordance with a further aspect of the invention, the minimum distance between the ground return wires and their associated signal carrying wire along a substantial length of the carrying wire is determined by the insulation on the ground return wires and/or their associated signal carrying wire. The position of the ground return wires relative to their associated signal carrying wire is determined by the location of the bonding locations on the chip and the bonding locations on the substrate. The ground return wires may be substantially symmetrical about their associated signal carrying wire and/or they made be substantially parallel to their associated signal carrying wire over a substantial length of the signal carrying wire.

In accordance with yet another aspect of the invention, the bonding locations on the chip are staggered to provide an effective pitch between the bonding locations of less than a wire diameter, and the bonding locations on the carrier substrate are staggered to provide an effective pitch between the bonding locations of less than a wire diameter.

Other aspects and advantages of the invention, as well as the structure and operation of various embodiments of the invention, will become apparent to those ordinarily skilled in the art upon review of the following description of the invention in conjunction with the accompanying drawings.

### BRIEF DESCRIPTION OF THE DRAWINGS

The invention will be described with reference to the accompanying drawings, wherein:

FIGS. 1A and 1B illustrate in front view and perspective view a first embodiment of the wire-based interconnect IC package in accordance with the present invention;

FIGS. 2A and 2B illustrate in front view and perspective view a second embodiment of the wire-based interconnect IC package in accordance with the present invention;

FIGS. 3A and 3B illustrate in front view and perspective view a third embodiment of the wire-based interconnect IC package in accordance with the present invention;

FIGS. 4A and 4B illustrate in front view and perspective view a fourth embodiment of the wire-based interconnect IC package in accordance with the present invention.

FIG. 5 is a graph illustrating signal integrity improvement with wirebond separation;

FIG. 6 is a graph illustrating a decrease in inductance with wirebond separation;

FIG. 7 is a graph illustrating transient rise-time with wirebond separation;

FIG. 8 is a graph illustrating signal integrity improvement with the number of ground return wires;

FIG. 9 is a graph illustrating signal integrity improvement with the length of the wirebonds;

FIG. 10 is a graph illustrating impedance decrease with wirebond separation and number of ground return wires;

FIG. 11 is a graph illustrating impedance decrease with wirebond separation and number of ground return wires with longer wirebonds; and

FIG. 12 is a graph combining the graphs in FIGS. 10 and 11.

### DETAILED DESCRIPTION

The wire-based interconnect IC package in accordance with the present invention uses one or more signal carrying wires to electrically connect a chip to a carrier substrate. The interconnect IC package further includes ground return wires associated with each signal carrying wire, the ground return wires are connected between the chip and the carrier substrate to conduct the return current for the signal carrying wire. Though both the signal carrying wire and the associated ground return wires, which are also called wirebonds, may be insulated, at least the signal carrying wire or the ground wires are insulated. The wirebonds are normally connected to the chip at bond pads and to the carrier substrate at bond fingers. By using insulated wirebond, the inductance of the signal carrying wires can be kept low by positioning a number of ground wires symmetrically about and in close proximity to the signal carrying wire. Though insulated wire is preferably used in the production of the interconnect IC package, uninsulated wire may be used to assemble the IC package followed by the coating of some or all of the wires with insulation.

Many types of insulated wire could be used to implement the invention described herein including an insulated wire known as X-Wire™ and manufactured by Microbonds, Inc. Further insulated wire that can be used with the present invention is described in U.S. Pat. No. 5,396,104, which issued to Kimura on Mar. 7, 1995, U.S. Pat. No. 5,031,821, which issued to Keneda, et al on Jul. 16, 1991, U.S. Pat. No. 5,037,023, which issued to Akiyama, et al On Aug. 6, 1991. Further wire types are described in US Patent Publication 2004/0119172A1, by Downey et al on Jun. 24, 2004 and in Harun, Fuaida et al., “An Evaluative Study of Insulated Wire in Ultra-Fine Pitch Applications”, Semicon S'Pore 2004 Proceedings. All of the above documents are incorporated herein by reference.

Experiments were conducted to determine design parameters using the insulated wire known as X-Wire™ that yielded improved interconnect IC package performance over conventional, uninsulated wire-based interconnect IC packages. Several variables were studied: wire length, distance between the wires, number of ground returns surrounding a signal-carrying wire, and configuration geometry of the signal-carrying wire and its associated ground wires.

The experiments were performed using industry standard high-speed electrical design simulators Zeland IE3D and Ansoft HFSS. Signal-carrying wires were terminated with a termination of 50 ohm, which is in the range impedance values for substrate signal traces in conventional packages.

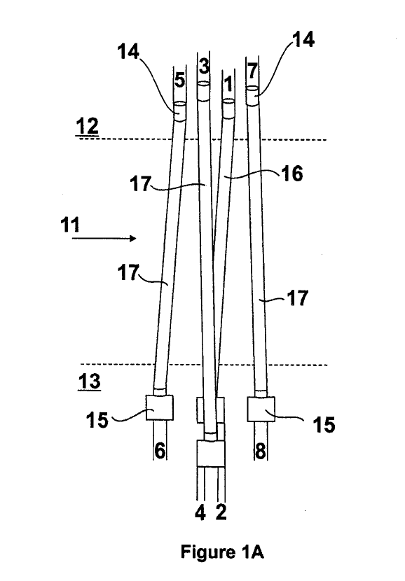

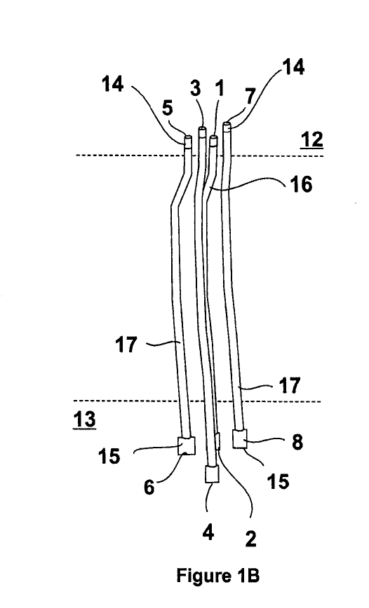

FIGS. 1A and 1B show a novel interconnect IC package 11 in which insulated wire is used for the signal carrying wire or line 16 and for the three ground return wires 17, which are placed adjacent to the signal wire 16. The wires 16, 17 electrically connect the chip 12 and the carrier substrate 13 between chip bond pads 14 and the substrate bond fingers 15. The locations of chip bond pads 14 are identified as 1, 3, 5 and 7, while the locations of the substrate bond fingers are identified as 2, 4, 6 and 8 for clarity. The signal wire 16 is connected between locations 1-2, while the ground return wires 17 are connected between locations 3-4, 5-6, and 7-8. The distance between bond pads 14 at locations 1, 3, 5 and 7 on the chip 12 is approximately 25 micrometers, while on the carrier substrate, the distance between bond fingers 15 at locations 2, 4, 6 and 8 is approximately 100 micrometers. During package manufacture, some sagging of wires 16, 17 is expected to occur, bringing these wires 16, 17 closer together. It can be appreciated that with conventional, uninsulated wires, sagging must not result in wires touching because this could be detrimental to performance. For this reason, in conventional packages using uninsulated wire, the pitch between bond pads on the chip is typically on the order of 35-50 micrometers for leading edge chips, 60-80 micrometers for advanced chips, and greater than 80 micrometers for standard chips; on the carrier substrate, the distance between bond fingers on a bond finger ring is typically 100 micrometers.

The novel use of thin film or round insulated wires allows for closer proximity of the ground wires to the associated signal wire with no detrimental effect on performance if the wires were to touch as a result of manufacturing tolerances.

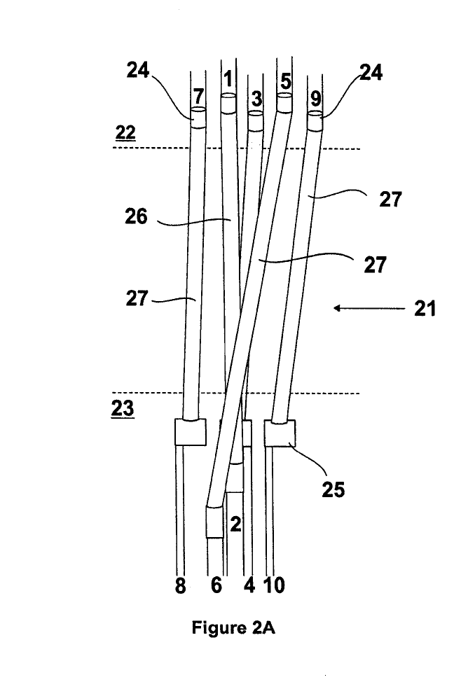

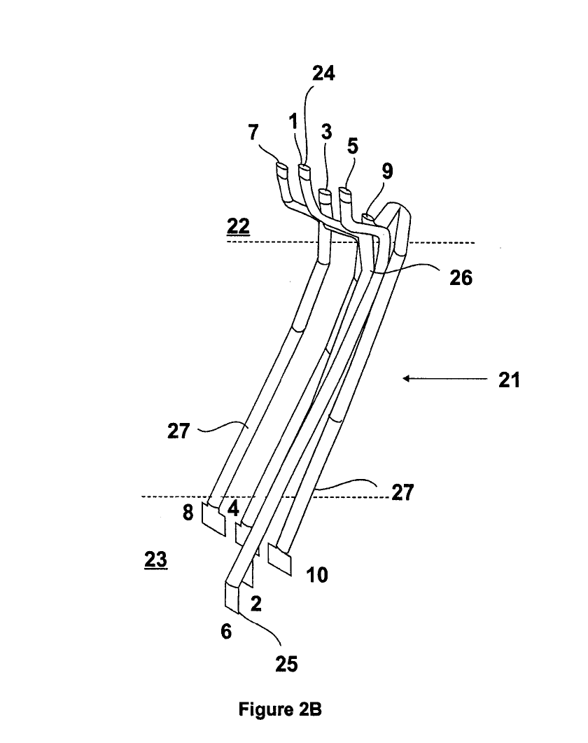

FIGS. 2A and 2B show a second embodiment of an interconnect IC package 21. Interconnect IC package 21 includes insulated wire for the signal carrying wire or line 26 and for the four ground return wires 27, which are placed adjacent to the signal wire 26. The wires 26, 27 electrically connect the chip 22 and the carrier substrate 23 between chip bond pads 24 and the substrate bond fingers 25. The locations of chip bond pads 24 are identified as 1, 3, 5, 7 and 9 while the locations of the substrate bond fingers are identified as 2, 4, 6, 8 and 10 for clarity. The signal wire 26 is connected between locations 1-2, while the ground current wires 27 are connected between locations 3-4, 5-6, 7-8 and 9-10. The distance of 25 micrometers between bond pads 24 at locations 1, 3, 5, 7 and 9 on the chip 22 and the distance of 100 micrometers between bond fingers 25 at locations 2, 4, 6, 8 and 10 on the carrier substrate 23 is maintained, however, the embodiment has an additional ground wire 27, bringing the number of grounds returns to four and thereby reducing the inductance of the ground path as compared to that for the embodiment in FIGS. 1A and 1B.

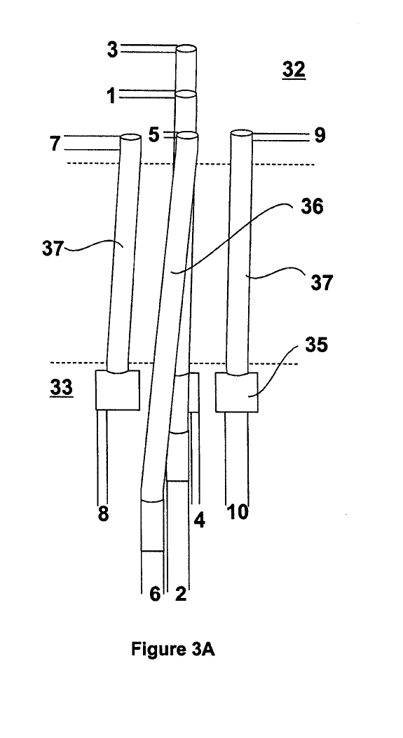

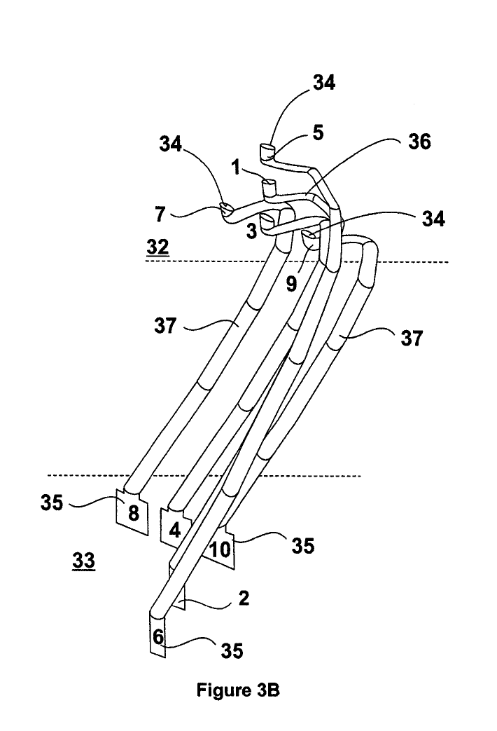

FIGS. 3A and 3B show a third embodiment of an interconnect IC package 31. In IC package 31, insulated wire is used for the signal carrying wire or line 36 and for the four ground return wires 37, which are placed adjacent to the signal wire 36. The wires 36, 37 electrically connect the chip 32 and the carrier substrate 33 between chip bond pads 34 and the substrate bond fingers 35. The locations of chip bond pads 34 are identified as 1, 3, 5, 7 and 9, while the locations of the substrate bond fingers 35 are identified as 2, 4, 6, 8 and 10 for clarity. The signal wire 36 is connected between locations 1-2, while the ground current return wires 37 are connected between locations 3-4, 5-6, 7-8 and 9-10. In FIG. 3A and 3B, the number of ground return wires 37 is identical to the embodiment in FIGS. 2A and 2B, however the effective pitch between bond pads 34 and between bond fingers 35 are both approximately 25 micrometers, reducing the distance between adjacent wires 36, 37 at the carrier substrate 33. By staggering the location of the bond pads 34 on the chip 32 and the bond fingers 35 on the carrier substrate 33, the ground wires 37 may be positioned closer and more symmetrically about the signal wire 36.

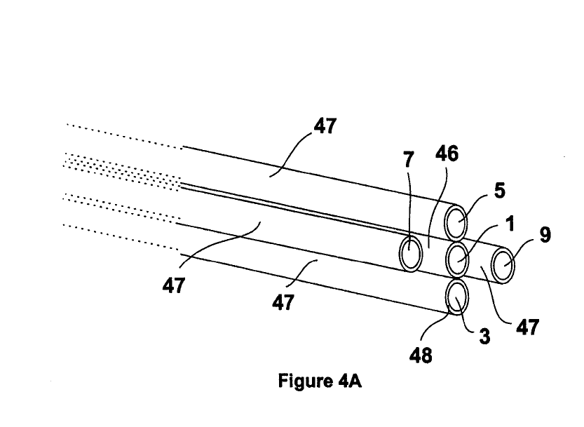

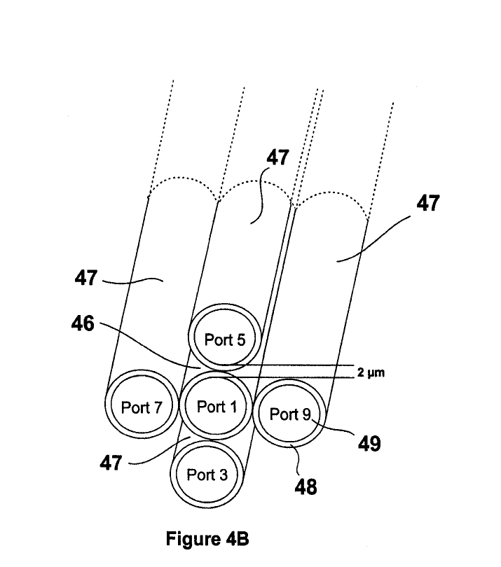

In FIGS. 4A and 4B, a fourth embodiment is illustrated to show the positioning of ground return wires 47 symmetrically about a signal wire 46 wherein insulated wire is again employed. The insulated wires 46, 47 consist of a conductive core 49 with an insulation coating 48. In this particular embodiment, the distance between the conductive core 49 of the signal wire 46 and the conductive cores 49 of adjacent ground wires 47 is approximately 2 micrometers since the thickness of the insulation 48 on each wire 46, 47 is approximately 1 micrometer. Therefore, the insulated ground wires 47 are adjoining or touching the signal carrying wire 46. This embodiment is also possible if only the signal wire 46 or only the ground wires 47 are insulated.

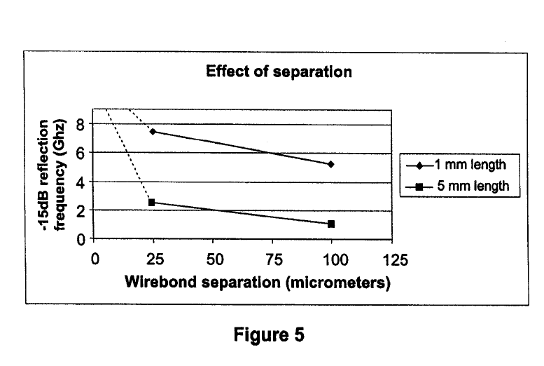

Tests performed with respect to the various embodiments showed that signal integrity improved as the distance between the signal wire 16, 26, 36, 46 and its associated surrounding ground return wires 17, 27, 37, 47 was reduced from conventional distances as illustrated in FIGS. 1A and 1B to wires that are substantially adjoining over a substantial length of the signal carrying wire as shown in FIGS. 4A and 4B where the distance between the conductive cores 49 is approximately 2 micrometers. As the ground return wires 17, 27, 37, 47 approach the bond pads and the bond fingers, the distance between the ground return wires 17, 27, 37, 47 and the signal wire 16, 26, 36, 46, increases in view of the pitch between the bond pads 14, 24, 34, 44 and the pitch between the bond fingers 15, 25, 35, 45. This improvement occurred for various lengths of wirebond, 1 mm and 5 mm length being illustrated. Signal integrity was assessed by considering the lowest frequency at which a −15 db reflection factor was observed; the higher this value, the better the signal integrity assessment. These results are shown on the graph in FIG. 5. With the distance between the conductive cores 49 of the signal wire 46 and the ground wire 47 at 2 micrometers, the −15 db reflection factor was greater than 10 GHz.

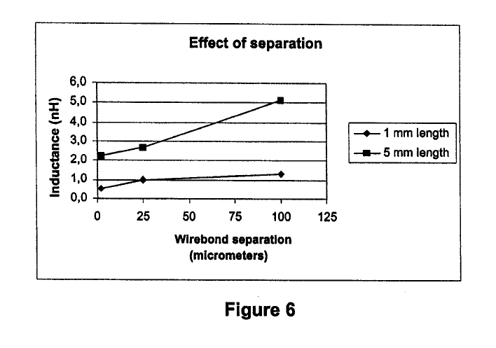

This improvement in signal integrity corresponded to a decrease in inductance, as illustrated on the graph in FIG. 6.

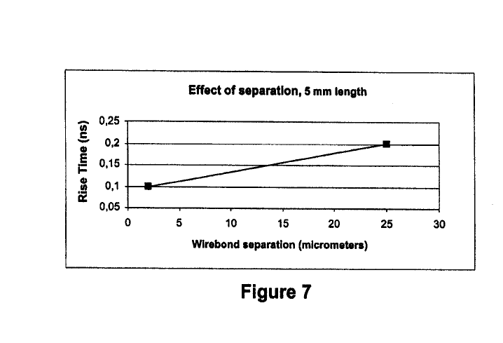

Transient results were also available for the embodiments described with regard to FIG. 3A and FIG. 4A with the wirebonds at 5 mm in length. For both of these geometries, a measurement was recorded of the time taken for a digital pulse input, injected into the wire, to rise to 90% of maximum voltage; the lower the measured rise time, the better the signal integrity. For the transient measurements, a digital pulse input with 50 ps rise time was used, and the signal-carrying wirebond was terminated with a 50-ohm impedance. The graph in FIG. 7 depicts the improvement in rise time as the distance between the conductive cores 49 of wires 46, 47 was decreased from 25 micrometers to 2 micrometers, a position where the insulated wires 46, 47 are substantially adjoining.

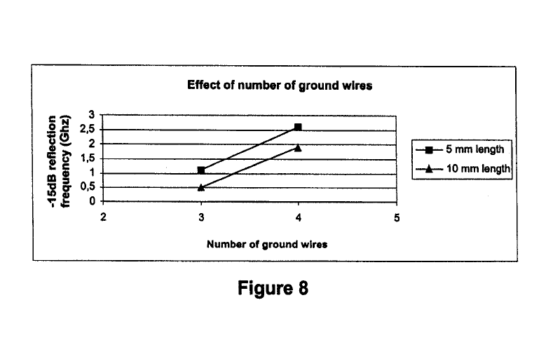

It was found that the number of ground wires also had an effect on signal integrity, the graph in FIG. 8 shows the effect of increasing the number of ground wires from 3 to 4 for 5 mm and 10 mm length wirebonds; signal integrity increased with the increased number of ground wires. Returning to FIG. 5, the embodiment in FIG. 1A has one fewer ground wires 17 running adjacent the signal-carrying wire 16 as compared to the other embodiments in FIGS. 2A, 3A and 4A, which contributes to the fact that the result for the embodiment in FIG. 1A as illustrated in FIG. 5 had the poorest signal integrity. It was also found that better results for signal integrity in FIG. 8 were for geometries with a lower inductance signal-carrying wire.

The novel use of insulated wire in wire-based IC packages can allow for a greater number of ground return wires to be placed adjacent to a signal-carrying wire as compared to the number that are possible in conventional wire-based interconnect IC packages without the risk of shorting the signal-carrying wire to the ground wire, and also for these ground wires to be placed closer to the signal-carrying wire over a substantial length of the signal carrying wire.

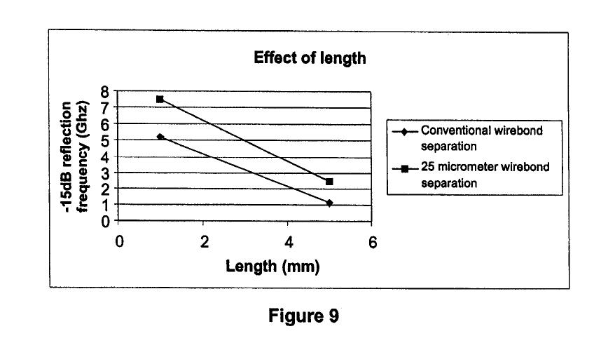

Further, as illustrated on the graph in FIG. 9, signal integrity increased with a decreased length of the wirebonds. FIG. 9 shows the effect of wire length for a conventional and a 25 micrometer spacing, over 1 to 5 mm.

The use of insulated wire in wire-based IC packages allows for adjacent bond pads and adjacent fingers to be placed closer together. This provides real estate on the chip and on the carrier substrate that can be used to move the pads and fingers to locations that make the wirebonds shorter than they would otherwise be in conventional ICs.

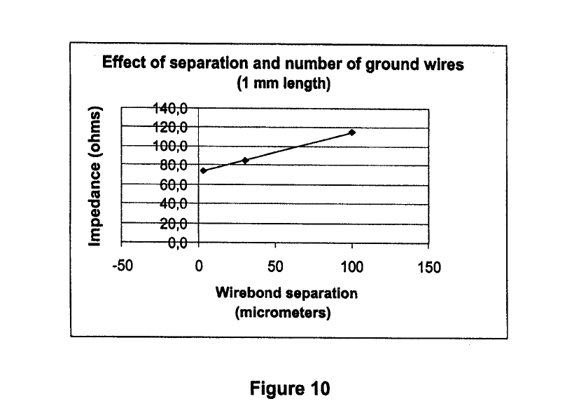

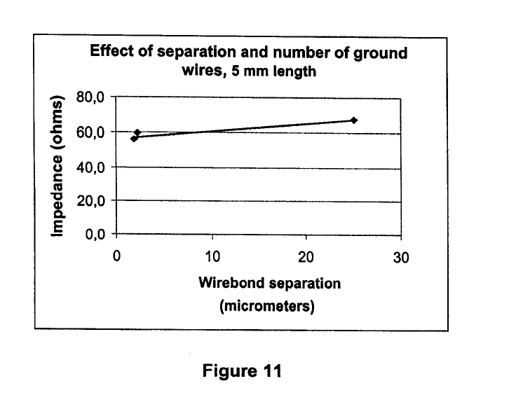

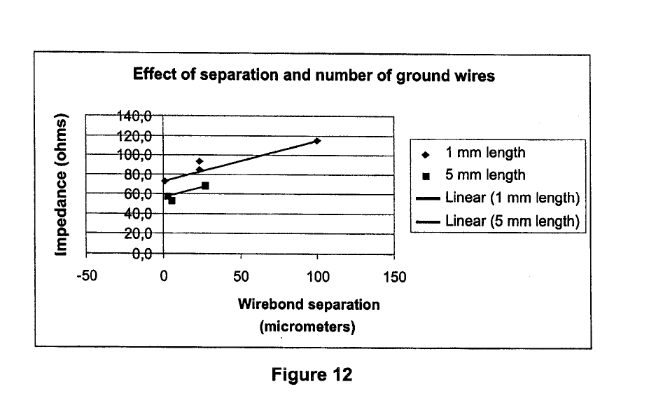

The best results were achieved for configurations that resulted in an impedance of the signal-carrying wirebond that most closely matched the impedance of the 50 ohm IC package signal path. The graph in FIG. 10 shows how combinations of separation and number of ground wires can decrease the impedance from a value for a 1 mm long conventional IC package of 110 ohm to near 50 ohm as these variables are varied. The graph in FIG. 11 shows the same for a 5 mm long wirebond. The two graphs in FIGS. 10 and 11 are superimposed on the graph in FIG. 12 to show the effect of varying the length from 1 mm to 5 mm. Linear regression trend lines are also shown. In FIGS. 10, 11 and 12, the configurations with 100 micrometer wire separation had three (3) ground wires and other configurations had four (4) ground wires

Additional experiments were conducted to determine the effect on electrical performance of the presence of the thin-film insulation of the insulated wire. The effect of the dielectric associated with the insulation was found to be negligible as compared to the dielectric that would surround the insulated wire in a finished package.

Because insulated wires can be in physical contact without detrimental effect on electrical performance, a novel design method can be followed. This method begins by choosing to use insulated wire in a signal-ground configuration for either the signal-carrying wirebond, the ground return wirebond(s), or both. Subsequent steps in the design method include allowing for physical contact between the insulated wirebonds (i.e., 2 micrometer between the conductive cores of the insulated wires) and reducing the inductance associated with one or more of the following variables: (1) the wirebond length; (2) the distance between the wirebonds in proximity of the bond pads; (3) the distance between the wirebonds in proximity of the bond fingers and (4) the signal-ground geometry (i.e., the position of the ground wire(s) relative to the signal-carrying wire). The design method could further involve reducing the impedance of the return path.

Minimizing the inductance associated with the wirebond length can be achieved by, first, determining the minimum distance between a bond pad and associated carrier finger and, second, choosing the wirebond length to allow for the minimum distance to be achieved.

Minimizing the inductance associated with the distance between the wires at the bond pads can be achieved by positioning adjacent bond pads as close as possible within a realistic range of manufacturing tolerances and/or staggering the bond pads on the substrate on which the bond pads are positioned.

Minimizing the inductance associated with the distance between the wires at the bond fingers can be achieved by positioning adjacent bond fingers as close as possible within a realistic range of manufacturing tolerances for the substrate on which the bond fingers are positioned and/or providing connection locations for the wirebonds outside of the bond fingers ring.

If multiple ground return wirebonds are employed, minimizing the inductance associated with the signal-ground geometry can be achieved by positioning ground wirebonds as symmetrically as possible around their associated signal wirebond. This involves staggering the bond pads of the ground wirebonds as symmetrically as possible around the bond pad for their associated signal wirebond. Similarly, the bond fingers of ground wirebonds are placed as symmetrically as possible around the bond finger for their associated signal wirebond.

Reducing the impedance of the return path can be achieved by placing the greatest number of associated ground returns as possible around a signal wirebond. This involves placing as many bond pads for ground returns on the chip substrate and as many associated bond fingers on the carrier substrate as possible. This can be achieved by staggering the bond pads and locating them as close as possible on the chip and by placing adjacent bond fingers as close as possible on the substrate and by providing further connection locations on the substrate.

Thus, it is seen that the present invention provides a wire-based IC package with improved signal integrity along its wire-based interconnections.

Further, the present invention also provides a method of design and manufacture of a wire-based IC package with improved signal integrity along its wire-based interconnections.

While the invention has been described according to what is presently considered to be the most practical and preferred embodiments, it must be understood that the invention is not limited to the disclosed embodiments. Those ordinarily skilled in the art will understand that various modifications and equivalent structures and functions may be made without departing from the spirit and scope of the invention as defined in the claims. Therefore, the invention as defined in the claims must be accorded the broadest possible interpretation so as to encompass all such modifications and equivalent structures and functions.

1-61. (canceled)

62. A wire-based interconnect IC package comprising:
one or more signal carrying wires adapted to electrically couple a chip to a carrier substrate; and
three or more ground current return wires positioned adjacent to each signal carrying wire and adapted to electrically couple the carrier substrate to the chip, the ground current return wires arranged to surround an adjacent signal carrying wire in a substantially symmetrical configuration wherein at least one of the signal carrying wires or the ground return wires are insulated.

63. The wire-based interconnect IC package as claimed in claim 62, wherein each of the signal carrying wires are insulated wires.

64. The wire-based interconnect IC package as claimed in claim 62, wherein the ground return wires are insulated wires.

65. The wire-based interconnect IC package as claimed in claim 62, wherein each of the signal carrying wires and the adjacent ground return wires are insulated wires.

66. The wire-based interconnect IC package as claimed in claim 62, wherein each signal carrying wire is electrically connected to the chip at a signal bond pad and electrically connect to the carrier substrate at a signal bond finger and the ground return wires are electrically connected to the chip at ground bond pads and electrically connect to the carrier substrate at ground bond fingers,
the ground bond pads surround the signal bond pad in a substantially symmetrical configuration; and
the ground bond finders surround the signal bond finger in a substantially symmetrical configuration.

67. In a wire-based interconnect IC package having one or more signal carrying wires and three or more ground current return wires positioned adjacent to each signal carrying wire for coupling a chip to a carrier substrate, the ground current return wires surrounding an adjacent signal carrying wire in a substantially symmetrical configuration, the signal carrying wires or the adjacent ground return wires comprising insulated wires.

68. In the wire-based interconnect IC package as claimed in claim 67, each signal carrying wire comprising insulated wire.

69. In the wire-based interconnect IC package as claimed in claim 67, each ground return wire comprising insulated wire.

70. In the wire-based interconnect IC package as claimed in claim 67, each signal carrying wire and the adjacent ground return wires comprising insulated wires.

71. In the wire-based interconnect IC package as claimed in claim 67, each signal carrying wire is electrically connected to the chip at a signal bond pad and electrically connect to the carrier substrate at a signal bond finger and the ground return wires are electrically connected to the chip at ground bond pads and electrically connect to the carrier substrate at ground bond fingers,
the ground bond pads surround the signal bond pad in a substantially symmetrical configuration; and
the ground bond finders surround the signal bond finger in a substantially symmetrical configuration.

72. The wire-based interconnect IC package as claimed in claim 66, wherein a distance between adjacent signal and ground bond pads is 25 micrometers or less.

73. The wire-based interconnect IC package as claimed in claim 71, wherein a distance between adjacent signal and ground bond fingers is 25 micrometers or less.
